(19) United States
(12) Patent Application Publication
(10) Pub. No.: US 2010/0327306 A1
(43) Pub. Date: Dec. 30, 2010

(54) LED BASED LIGHT SOURCE FOR IMPROVED COLOR SATURATION

(75) Inventors: Petrus Johannes Mathijs Van Der Burgt, Eindhoven (NL); Rene Theodorus Wegh, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/865,872

(22) PCT Filed: Feb. 5, 2009
(86) PCT No.: PCT/IB2009/050473

§ 371 Date: Aug. 3, 2010

(30) Foreign Application Priority Data
Feb. 11, 2008 (EP) 08151250.1

(51) Int. Cl. H01L 33/50; H01L 33/60

(52) U.S. Cl. 257/98; 257/E33.072

(57) ABSTRACT

There is provided a light emitting device comprising a light source comprising at least one light emitting diode emitting visible radiation. The light emitting device further comprises a wavelength converting body comprising a first wavelength converting material, which is arranged to receive light emitted by said light source and which has an emission maximum in the range of from 600 to 700 nm. The first wavelength converting material comprises the elements Mg, Ge, O and Mn. A light emitting device according to the invention produces light having increased saturation of red colors. Moreover, long life and good color stability is achieved.

### FIELD OF THE INVENTION

The invention relates to a light emitting device comprising a light emitting diode based light source and a wavelength converting body comprising a wavelength converting material arranged to receive light emitted by said light source.

### BACKGROUND OF THE INVENTION

In many instances such as retail or trade fairs it is desirable to present articles, e.g. fresh food, in an attractive way. With regard to illumination, usually this means that the colors of the articles should be enhanced, in other words that the articles should show more saturation of color.

Today usually compact high intensity discharge lamps, such as ultra high pressure sodium lamps (e.g. SDW-T lamps) or special fluorescent lamps are used for this purpose. In the case of an ultra high pressure sodium lamp an additional filter is often used to obtain the required saturation, leading however to low system efficacy. Furthermore the ultra high pressure sodium lamps have a short life (approximately 6000 hours) and are not stable in color over this life span. The drawbacks of fluorescent lamps are the linear size and length resulting in limitation of application possibilities.

A light emitting diode (LED) based solution can in principle be used to overcome the above disadvantages. By combining light emitting diodes (LEDs) with different spectral outputs in the desired proportion, e.g. blue, green, amber and red, a total spectral output giving saturation of certain colors can be obtained. However, drawbacks of this solution are low efficiency and complexity of the system, as the use of different colors of LEDs leads to complex binning issues. Moreover, to maintain color point stability a complex control system is required, since particularly red LEDs exhibit strong changes in output spectra with current and temperature. As a result, the cost of the lamp is high.

In general lighting applications, some disadvantages of systems with LEDs of different colors can be overcome by using only blue LEDs and conversion of part of the blue light by a phosphor (wavelength converting material) to obtain white light output. However, a drawback of many blue light converting phosphors with regard to specialized illumination applications is that they generally exhibit a broad emission spectrum, and thus high saturation of colors cannot be achieved.

Thus, there is a need for an illumination device by which high saturation of colors can be achieved, which is efficient, has long life and exhibits good color stability.

### SUMMARY OF THE INVENTION

It is an object of the present invention to at least partly overcome the above mentioned drawbacks of the prior art and to provide a LED based light emitting device by which high color saturation can be obtained.

The inventors have found that the use of a special red phosphor, excited by visible radiation emitted from an LED and emitting light in the red light wavelength range, results in the emission of light having very desirable spectral properties for certain applications. In particular, the saturation of red colors is increased.

Thus, in one aspect, the invention relates to a light emitting device comprising a light source comprising at least one light emitting diode emitting visible radiation; and a wavelength converting body comprising a first wavelength converting material arranged to receive light emitted by said light source and having an emission maximum in the wavelength range of from 600 to 700 nm, said first wavelength converting material comprising the elements Mg, Ge, O and Mn.

The at least one light emitting diode typically has an emission maximum in the range of from 400 to 450 nm, and preferably about 420 nm. Surprisingly, the inventors found that excitation of Mg₄GeO_{5.5}F:Mn by blue light in the wavelength range of 400-450 nm may provide good conversion efficiency, even though Mg₄GeO_{5.5}F:Mn has a rather weak absorption band with a maximum at about 420 nm.

Preferably, the light source further comprises a reflective material, such as a reflective layer. A reflective layer will redirect light that is scattered backwards from the light source and converted light that is emitted backwards by the wavelength converting body to increase the light output of the light emitting device. As a result, the efficacy of the light emitting device is increased.

Preferably, the light source and said wavelength converting body are arranged mutually spaced apart. By introducing a spacing between the light source and the wavelength converting body, the efficiency of the device may be improved, as light that is scattered or emitted back into the light mixing chamber is spread more effectively. In particular, the efficacy of the light emitting device is greatly improved by a combination of a spacing between the light source and the wavelength converting body and the use of a reflective material, as the light then can be even more effectively redirected to exit the light emitting device.

Furthermore, at least the light source and the wavelength converting body may delimit a light mixing chamber. Optionally, the light emitting device further comprises a side wall at least partly extending between the light source and the wavelength converting body. The use of a side wall prevents light from escaping in an undesired direction and may be used as a substrate for various other components, for example a reflective layer. Typically, at least a part of the side wall is reflective.

A reflective side wall allows redirection of light that is scattered or emitted back into the light mixing chamber by the wavelength converting body to increase the light output of the light emitting device. Thus, the efficacy of the device may be increased.

Furthermore, the light emitting device further comprises a second wavelength converting material having an emission maximum between the emission maximum of the light source and the emission maximum of the first wavelength converting material. The combination of the first wavelength converting material with a conventional green phosphor (emitting light in the wavelength range of 500-550 nm) has been found to be particularly advantageous, as high color saturation in the green hue range hence is obtained in addition to high red saturation. A light emitting device comprising both said first and second wavelength converting materials thus gives very high saturation of red and green colors while the overall color rendering is still acceptable. High red and green color saturation is very desirable in certain applications, for example illumination of fresh food articles such as fresh meat, fish, fruit and vegetables, but it may also be advantageous in various other retail and exposition illumination applications. Moreover, a light emitting device comprising a blue LED and a wavelength converting body comprising a first wavelength converting material according to embodiments of the invention can be advantageously used for e.g. outdoor lighting purposes since energy efficiency is high, the color rendering index (CRI) is acceptable for this application, and high saturation of red color gives improved facial recognition by saturation of skin colors.

Moreover, using a light emitting device according to as described above, long life and stable colors may be obtained.

When the light emitting device comprises a second wavelength converting material, a light source emitting light of wavelengths up to 450 nm may be particularly preferred, as these wavelengths may provide better excitation of the green phosphor than wavelengths of about 420 nm. The second wavelength converting material typically comprises the elements Lu, Al, O and Ce.

In addition to the first wavelength converting material, the wavelength converting body may also comprise said second wavelength converting material. By incorporating both wavelength converting materials in the wavelength converting body, for example by mixing both materials in the wavelength converting body, the production of the light emitting device is rendered simpler and more cost-efficient compared to applying the wavelength converting materials separately at different locations in the light emitting device. However, separating the wavelength converting materials can provide better color control and minimize undesired interaction between the phosphors. Therefore, the second wavelength converting material may for example be provided on at least a part of the side wall.

The light emitting device may further comprise a light diffusing layer arranged to diffuse the light exiting from the light emitting device. A light diffusing layer enables shaping of the light exiting the light emitting device in a desired pattern. Thus, the light emitting device can be adapted to suit various user requirements.

For example, the wavelength converting body may comprise the light diffusing layer.

### BRIEF DESCRIPTION OF THE DRAWINGS

FIG. 1 is a schematic illustration of a light emitting device according to an embodiment of the invention.

FIG. 2 is a graph showing the total output spectrum of a light emitting device according to an embodiment of the invention.

### DETAILED DESCRIPTION OF THE INVENTION

The inventors have surprisingly found that the use of a special red wavelength converting material in combination with a light emitting diode (LED) emitting visible radiation results in the emission of light having very desirable spectral properties for certain applications, as the saturation of red colors is increased. According to the invention, there is provided a light emitting device comprising a light source comprising at least one light emitting diode emitting visible radiation. The light emitting device further comprises a wavelength converting body comprising a first wavelength converting material arranged to receive light emitted by said light source. The wavelength converting material emits light in the wavelength range of from 600 to 700 nm and comprises the elements Mg, Ge, O and Mn. The first wavelength typically has a narrow emission spectrum in the wavelength range 600-700 nm with a maximum at about 660 nm. The invention will now be described in detail with reference to the appended drawings.

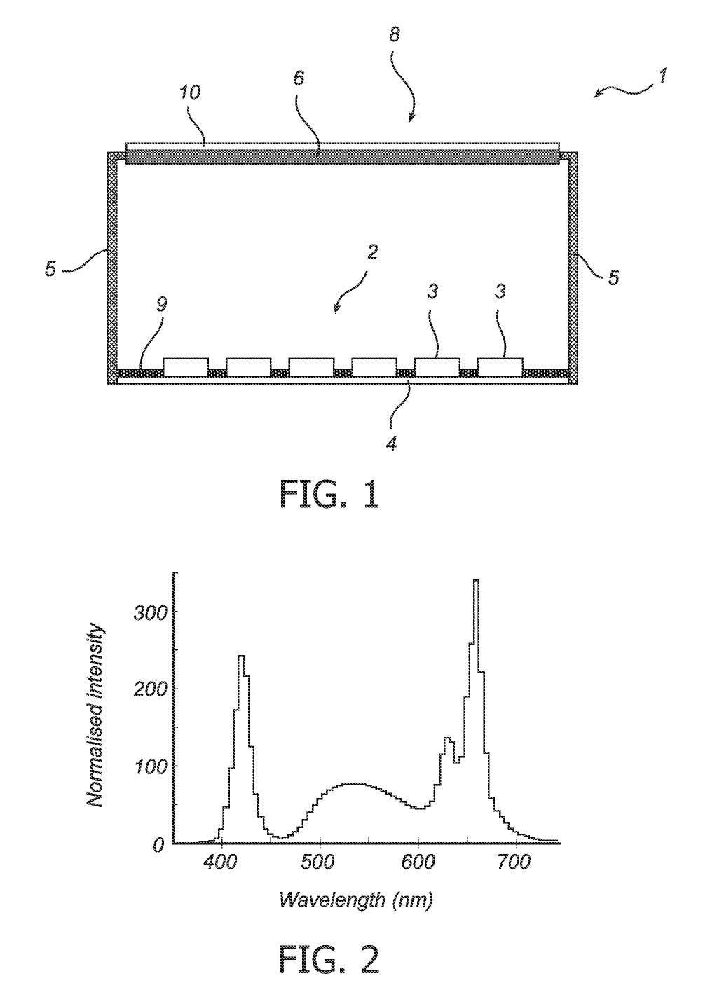

FIG. 1 shows a light emitting device 1 according to one embodiment of the invention. A light source 2 is provided at the bottom of the device. The light emitting device 1 may a downlight module, an uplight module and may form part of e.g. a shelf light system.

The light source 2 comprises a plurality of light emitting diodes (LEDs) 3 provided on a substrate 4. The LEDs are designed to emit visible radiation. Preferably the light source has an emission maximum in the wavelength range of from 400 to 450 nm, and more preferably about 420 nm.

Furthermore, a wavelength converting body 6 comprises a first wavelength converting material arranged to receive light emitted by the light source 2. The wavelength converting material comprises the elements Mg, Ge, O and Mn (herein also referred to as MGM). Typically, an MGM-material comprises the compounds MgO, GeO₂ and MnO. Additionally, an MGM material may comprise additional elements, such as F and/or Sn. The presence of fluorine typically improves the temperature dependence characteristics of the MGM material. However, in the present invention, the temperature of the first wavelength converting material is typically low, and therefore the presence of fluorine, or another element having a similar function, in the wavelength converting material is optional. When fluorine is present, it may be in the form of MgF₂, and the amount thereof may vary. A possible alternative to MgF₂ is BeO (e.g. GB 701,033 A).

One example of a first wavelength converting material (an MGM material) according to the invention is Mg₄GeO_{5.5}F:Mn. Another example, in which fluorine is not present, is Mg₄GeO₆:Mn. However, the stoichiometric ratios between the elements Mg, Ge, O and Mn may differ between MGM materials provided by different manufacturers. Mg₄GeO_{5.5}F:Mn and Mg₄GeO₆:Mn are therefore to be considered as approximate formulae. Stoichiometric formulae slightly different from those described above are also possible to use according to the invention.

MGM has a narrow emission spectrum in the wavelength range of from 600 to 700 nm with a maximum at about 660 nm. MGM is a known phosphor for use under UV excitation, and is used e.g. in red-saturated fluorescent lamps for illumination of meat. Surprisingly, the use of MGM in combination with a light source emitting visible radiation, in particular light in the range of from 400 to 450 nm, has now been found to produce a spectral power distribution of light which includes higher saturation of red colors.

The absorption spectrum of MGM shows a rather weak absorption band with maximum at about 420 nm. Consequently, in order to maximize the emission output from the wavelength converting material, a light source emitting light of about 420 nm is preferred.

When pumped with blue light (400-450 nm), a rather thick MGM layer is needed to achieve sufficient conversion of blue light. However, the efficacy of the light emitting device may be improved by providing the device with a reflective material for directing light emitted by an LED towards the wavelength converting body and/or reflecting light that is scattered or emitted back towards the light source by the wavelength converting body. In this way, the light may be directed in a light output direction of the light emitting device. In FIG. 1, side walls 5 extend between the light source 2 and the wavelength converting body 6. Optionally at least a part of the side wall 5 is reflective. For example, the side wall 5 may be provided with a reflective layer facing the wavelength converting body. Any conventional reflective material may be used for the reflective layer, such as a metal or a white reflective film. The side walls 5 of FIG. 1 may form part of one continuous side wall.

Moreover, the substrate 4 is covered with a layer of a highly reflective material 9 to ensure good redirection of backward scattered or emitted light. In embodiments of the invention, the light source 2 comprises a reflective substrate. Optionally, the at least one LED may be arranged on such a reflective substrate.

In FIG. 1, the light source 2 and the wavelength converting body 6 are arranged mutually spaced apart. When there is a spacing between the wavelength converting body and the light source, a lesser part of the light emitted by the wavelength converting body is directed towards an LED die where it is absorbed, compared to an arrangement in which the wavelength converting body is arranged adjacent to the light source. Thus a spacing between light source and the wavelength converting body allows for an increase in efficacy. For example, the wavelength converting body 6 may be located in the path of light between the light source 2 and an exit window 8, preferably near the exit window. In the embodiment shown in FIG. 1, the wavelength converting body 6 is located in the exit window 8.

When the light source and the wavelength converting body are arranged mutually spaced apart, a reflective material may be provided as described above in order to even further improve the efficacy of the light emitting device.

In embodiments of the invention, the light source 2 and the wavelength converting body 6 delimit a light mixing chamber. Optionally, a light mixing chamber may be defined by additional structures, such as a side wall. In FIG. 1, the light source 2, the wavelength converting body 6 and the side wall 5 delimit a light mixing chamber, in which light emitted by the light source 2 may be mixed with wavelength converted light. The light exits the light mixing chamber via the exit window 8. When the light emitting device comprises a reflective material, the reflective material is typically arranged to redirect light emitted from the light source towards the wavelength converting body or a wavelength converting material, and/or to redirect light towards the exit window in order to increase the output of light of the desired wavelengths from the light mixing chamber.

Using a visible LED-MGM phosphor combination a long life, stable color can be expected. Furthermore, a lighting system comprising a light emitting device according to the invention can be made compact, enabling the design of compact luminaries. The efficacy of a light emitting device as described herein is currently comparable with that of ultra high pressure sodium systems using filters, and is expected to exceed the efficacy of ultra high pressure sodium lamps within a few years as the performance of the LEDs will improve.

Furthermore, the wavelength converting body 6 may comprise a second wavelength converting material. Typically, the light emitting device comprises a second wavelength converting material having an emission maximum between the emission maximum of the light source and the emission maximum of the first wavelength converting material, preferably in the green light wavelength range. Any conventional green wavelength converting material may be used, for example a material comprising the elements Lu, Al, O and Ce, such as Lu₃Al₅O₁₂:Ce (herein also referred to as LuAG). The stoichiometric formula Lu₃Al₅O₁₂:Ce is approximate and small deviations from this formula are possible, as well as the incorporation of additional elements, as will be readily appreciated by a person skilled in the art. The combination of a first wavelength converting material, a second wavelength converting material and a light source as described above has been found to provide a very high saturation of red and green colors. In particular, the use of LuAG in a light emitting device according to the above description provides very high saturation of red and green colors while the overall color rendering is still sufficient (CRI 70). White light of various color temperatures may be obtained.

It shall be noted that any reference herein to “wavelength converted light” refers to light that has been converted by any wavelength converting material present in the light emitting device, for example the first wavelength converting material and/or the second wavelength converting material.

The second wavelength converting material may be provided at any suitable location in the light emitting device. For example, the second wavelength converting material may be disposed on at least a part of the side wall portion. A side wall portion covered by wavelength converting material, such as the first wavelength converting material or the second wavelength converting material, may be reflective in order to reflect light transmitted or emitted by the wavelength converting material. Thus, light that is transmitted or emitted by a wavelength converting material may be reflected back into the light mixing chamber and subsequently exit the light emitting device in a desired direction, for example through an exit window. Furthermore, the second wavelength converting material may be at least partially comprised in the wavelength converting body. For example, the second wavelength converting material may be mixed with the first wavelength converting material. Alternatively, the second wavelength converting material and the first wavelength converting material may occupy separate regions of the wavelength converting body. For example, the second wavelength converting material and the first wavelength converting material may form separate layers.

When a second wavelength converting material is used in combination with the first wavelength converting material, it may be advantageous to use a light source emitting light of wavelengths longer than 420 nm, for example up to 450 nm, as better excitation of the second wavelength converting material may then be obtained. Additionally, LEDs emitting light at about 450 nm being more commercially available than 420 nm LEDs, a light source emitting at about 450 nm might provide a more economically attractive alternative.

In the embodiment shown in FIG. 1, the wavelength converting body 6, which is located at the exit window 8, also comprises a diffusing layer 10 shaping the light beam to a desired radiation pattern. Optionally, a wavelength converting material, e.g. the first and/or the second wavelength converting material, may be arranged as a coating on the light diffusing layer 10. Alternatively, a wavelength converting material may be incorporated in the light diffusing layer 10. Moreover, a wavelength converting material may be provided adjacent to the light diffusing layer, e.g. on a transmissive substrate.

Furthermore, a reflector can be placed at the exit window 8 of the light emitting device 1 to generate a desired beam pattern. The device 1 may also be provided with a housing at which heatsinks, reflectors and luminaire housing parts can be fixed.

The at least one LED may be positioned on a heatspreader used to connect the light emitting device with heatsinks to ensure proper thermal management. A LED driver powers the LED module with the desired current. The LED driver can be fixed output, but can also be dimmable.

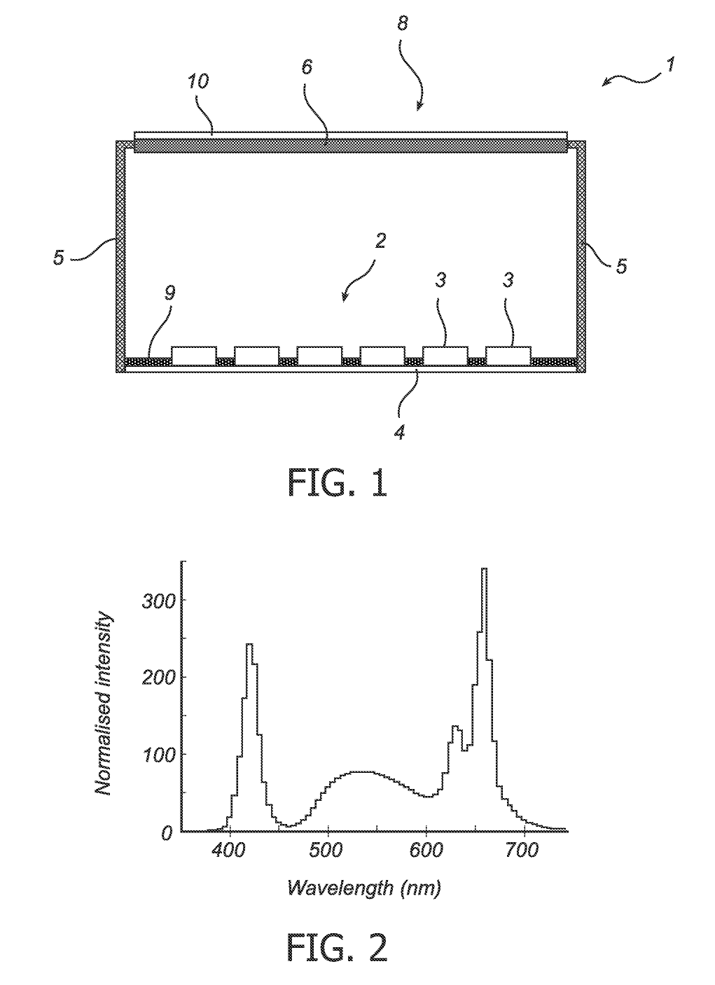

FIG. 2 shows the experimental total output spectrum of a light emitting device comprising a 420 nm blue LED pump as light source, a first wavelength converting material comprising MGM, and LuAG as a second wavelength converting material. The device emits white light with a corrected color temperature (CCT) of 3800 K. However, white light of various other color temperatures may be obtained as well.

In order to represent the increase in saturation obtained by an embodiment of the invention, the average saturation for more than 6000 colors in the hue range from red to yellow was calculated for a conventional SDW-T system (an ultra high pressure sodium system) and the above LED-MGM-LuAG system, respectively, using a Planckian radiator as a reference illuminant. In this hue range the colors of meat products, fish, fruits and many vegetables are found. The average saturation for this hue range is expressed as a relative saturation number representing the increase in color saturation relative to the reference illuminant. For the green hue range similar data can be derived.

The resulting calculated relative saturation numbers are presented in Table 1 below.

TABLE 1
Average saturation compared to a Planckian radiator

| | Relative saturation number | |
|---|---|---|
| | Red hue range | Green hue range |
| SDW-T | 0.61 | -0.6 |
| LED-MGM-LuAG | 1.21 | 1.14 |

These results indicate that for illumination applications requiring high saturation of red and green colors, for example illumination of fresh food, a blue LED-MGM-LuAG system is expected to perform much better than a conventional SDW-T system. For the SDW-T system above, the average saturation for the reddish to yellow colors was much lower (0.61 versus 1.11) than the LED-MGM-LuAG, thus demonstrating higher color saturation for the LED system. In the range of greenish colors the LED-MGM-LuAG system was superior (1.14 versus −0.6).

It shall be appreciated that the above description is illustrative and not limitative of the scope of the invention. For example, the invention also comprises any type of lighting system comprising at least one light emitting device as described above and provided with appropriate driving electronics and possibly also heat spreaders, light guides or any other optical elements, and a supporting structure.

A light emitting device according to the above description can be advantageously used in an illumination system for applications in which high saturation of red colors, and optionally of green colors, is desirable, such as retail, trade fairs, shows, museums, exhibitions, galleries and various other expositions, as well as outdoor lighting.

1. Light emitting device comprising:
a light source comprising at least one light emitting diode emitting visible radiation; and
a wavelength converting body comprising a first wavelength converting material arranged to receive light emitted by said light source and having an emission maximum in the wavelength range from about 600 to about 700 nm, said first wavelength converting material comprising the elements Mg, Ge, O and Mn.

2. Light emitting device according to claim 1, wherein said light source has an emission maximum in the wavelength range from about 400 to about 450 nm.

3. Light emitting device according to claim 1, wherein said light source further comprises a reflective layer.

4. Light emitting device according to claim 1, wherein said light source and said wavelength converting body are arranged mutually spaced apart.

5. Light emitting device according to claim 1, wherein at least said light source and said wavelength converting body delimit a light mixing chamber.

6. Light emitting device according to claim 1, further comprising a side wall at least partly extending between said light source and said wavelength converting body.

7. Light emitting device according to claim 6, wherein at least a part of said side wall is reflective.

8. Light emitting device according to claim 1, further comprising a second wavelength converting material having an emission maximum between the emission maximum of the light source and the emission maximum of said first wavelength converting material.

9. Light emitting device according to claim 8, wherein said second wavelength converting material comprises the elements Lu, Al, O and Ce.

10. Light emitting device according to claim 8, wherein said wavelength converting body comprises said second wavelength converting material.

11. Light emitting device according to claim 8, wherein said second wavelength converting material is provided on at least a part of a side wall.

12. Light emitting device according to claim 1, further comprising a light diffusing layer arranged to diffuse the light exiting said light emitting device.

13. Light emitting device according to claim 12, wherein said wavelength converting body comprises said light diffusing layer.
